(19) United States
(12) Patent Application Publication
(10) Pub. No.: US 2009/0179670 A1
(43) Pub. Date: Jul. 16, 2009

(54) PERFORMANCE INVERSION DETECTION CIRCUIT AND A DESIGN STRUCTURE FOR THE SAME

(75) Inventors: Albert M. Chu, Essex, VT (US); John A. Fifield, Underhill, VT (US); Daryl M. Seitzer, Essex Junction, VT (US); Hongfei Wu, Colchester, VT (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 12/014,430

(22) Filed: Jan. 15, 2008

(51) Int. Cl. H03F 3/45

(52) U.S. Cl. 327/52

(57) ABSTRACT

A circuit containing a parallel connection of a first sub-circuit and a second sub-circuit is provided. The first sub-circuit comprises a serial connection of a first field effect transistor having a first threshold voltage and a first voltage dividing device. The second sub-circuit comprises a serial connection of a second field effect transistor having a second threshold voltage, which is different from the first threshold voltage, and a second voltage dividing device. The voltage between the first field effect transistor and the first voltage dividing device is compared with the voltage between the second field effect transistor and the second voltage dividing device so that a signal may be generated at a temperature at which the ratio of a performance parameter such as on-current between the first and second field effect transistors crosses over a predefined value. The signal may be advantageously employed to actively control circuit characteristics.

### FIELD OF THE INVENTION

The present invention relates to a semiconductor circuit for detecting performance inversion of a set of semiconductor transistors, and a design structure for the same.

### BACKGROUND OF THE INVENTION

Temperature delay inversion occurs when devices with relatively high threshold voltages operate at low voltage. Transistor on-current (Idsat) is influenced by temperature in two ways. Idsat is proportional to a charge carrier mobility, i.e., hole mobility or electron mobility, which increases at low temperature and decreases at high temperature. Idsat is also proportional to the difference between a gate-to-source voltage and a threshold voltage, i.e., Vgs−Vt. The threshold voltage Vt increases at low temperature and decreases at high temperature. Given the same gate-to-source voltage, Vgs−Vt decreases at low temperature and increases at high temperature. While these two factors influence the on-current in opposite ways, their respective contributions are not proportional to each other. For devices operating at a relatively high power supply Vdd above 10.5V, Vgs−Vt is large enough to contribute only a small fractional change in the on-current so that the temperature dependency of the on-current is dominated by the temperature dependency of the charge carrier mobility. Historically, therefore, it has been assumed that circuits would be slowest at high temperatures.

However, continual reduction in the power supply voltage has led to development of low power technology employing low power devices operating typically below 1.0 V for the power supply voltage. Such low power technologies employ multiple transistor types each having different threshold voltages. The higher the threshold voltage, the lower the power consumption of the device tends to be. Some devices operate at small value for the difference between a gate-to-source voltage and a threshold voltage (Vgs−Vt), however, the fractional variation in Vgs−Vt due to temperature variation can be greater than the fractional variation in the charge carrier mobility due to temperature variation. Such tendency is most prominent for high threshold voltage (high Vt) devices, while low threshold voltage (low Vt) devices may have a temperature dependence of on-current that is predominantly determined by the charge carrier mobility. Specifically, high threshold voltage devices may have more on-current at a high temperature, e.g., at 125° C., than at a low temperature, e.g., at −40° C., while low threshold voltage devices may have less on-current at the same high temperature than at the same low temperature. The phenomenon of a device operating at a low temperature, e.g., at −40° C., having a less on-current than at a high temperature, e.g., at 125° C., is called low temperature performance inversion, or “temperature inversion” of performance.

Mixed employment of such high threshold voltage devices and low threshold voltage devices, which is common in today's low power technologies, creates a conundrum. Sections of a circuit containing high threshold voltage devices operate slower at low temperatures than at high temperatures, while other sections of the circuit containing low threshold voltage devices operate slower at high temperatures. Picking the worst case corner to simulate to time the operation of the circuit becomes a challenge since different devices have worst performance at different temperatures. An industry standard approach is to pick the worst case corner for circuit operation conditions and to close timing assuming that the picked worst corner provides the slowest condition the circuit will operate at. Even if timing closure was expanded to cover both the extreme high and low temperature points, this would not ensure the slowest point in temperature would be covered in a mixed Vt design. Furthermore, the uncertainty of what is the slowest point could result in overly pessimistic estimation. This may lead to failure to close timing, or an over reliance on lower Vt devices which would adversely affect the standby current.

In view of the above, there exists a need for alleviating temperature dependency of a circuit employing mixed threshold voltage devices. Particularly, there exists a need to detect a reference temperature at which the relative performance between one type of device having a one threshold voltage and another type of device having another threshold voltage crosses over a predefined value so that overall performance of the circuit may be adjusted.

### SUMMARY OF THE INVENTION

To address the needs described above, the present invention provides semiconductor circuit for detecting temperature dependency of relative performance of two types of devices having different threshold voltages

In the present invention, a circuit containing a parallel connection of a first sub-circuit and a second sub-circuit is provided. The first sub-circuit comprises a serial connection of a first field effect transistor having a first threshold voltage and a first voltage dividing device. The second sub-circuit comprises a serial connection of a second field effect transistor having a second threshold voltage, which is different from the first threshold voltage, and a second voltage dividing device. The voltage between the first field effect transistor and the first voltage dividing device is compared with the voltage between the second field effect transistor and the second voltage dividing device so that a signal may be generated at a temperature at which the ratio of a performance parameter such as on-current between the first and second field effect transistors crosses over a predefined value. The signal may be advantageously employed to actively control circuit characteristics.

According to an aspect of the present invention, a semiconductor circuit is provided, which comprises a parallel connection of a first sub-circuit and a second sub-circuit and a differential amplifier, wherein the first sub-circuit comprises a serial connection of a first field effect transistor having a first threshold voltage and a first voltage dividing device, wherein the second sub-circuit comprises a serial connection of a second field effect transistor having a second threshold voltage and a second voltage dividing device, wherein the first threshold voltage is different from the second threshold voltage, and wherein a first voltage from a first internal node between the first field effect transistor and the first voltage dividing device and a second voltage from a second internal node between the second field effect transistor and the second voltage dividing device are compared by the differential amplifier.

In one embodiment, the first field effect transistor and the second field effect transistor are p-type field effect transistors, and wherein a first source of the first field effect transistor and a second source of the second field effect transistor are directly connected to each other.

In another embodiment, the first voltage dividing device is a first n-type field effect transistor and the second voltage dividing device is a second n-type field effect transistor, and wherein a third source of the first n-type field effect transistor and a fourth source of the second n-type field effect transistor are directly connected to each other.

In even another embodiment, the first n-type field effect transistor has a third threshold voltage and the second n-type field effect transistor has a fourth threshold voltage, wherein the first threshold voltage is greater than the second threshold voltage and the fourth threshold voltage is greater than the third threshold voltage.

In yet another embodiment, the first voltage dividing device is a first resistor and the second voltage dividing device is a resistor, and wherein an end terminal of the first resistor is directly connected to an end terminal of the second resistor.

In still another embodiment, the first source and the second source are connected to a positive power supply.

In still yet another embodiment, the first field effect transistor and the second field effect transistor are n-type field effect transistors, and wherein a first source of the first field effect transistor and a second source of the second field effect transistor are directly connected to each other.

In a further embodiment, the first voltage dividing device is a first resistor and the second voltage dividing device is a resistor, and wherein an end terminal of the first resistor is directly connected to an end terminal of the second resistor.

In an even further embodiment, the semiconductor circuit further comprises a circuit enable transistor that is serially connected to the parallel connection and configured to function as a switch between the parallel connection and one of ground and a positive power supply.

In a yet further embodiment, the first field effect transistor and the second field effect transistor are constantly turned on and the first voltage dividing device and the second voltage dividing device are configured to pass current upon application of a voltage differential thereacross.

According to another aspect of the present invention, a design structure embodied in a machine readable medium for designing, manufacturing, or testing a design is provided. The design structure represents a semiconductor circuit and comprises:

a first data representing a first serial connection of a first field effect transistor having a first threshold voltage and a first voltage dividing device;

a second data representing a second serial connection of a second field effect transistor having a second threshold voltage and a second voltage dividing device; and

a third data representing a differential amplifier, wherein the first connection and the second serial connection are configured in a parallel connection in the semiconductor circuit, and wherein a first internal node between the first field effect transistor and the first voltage dividing device and a second internal node between the second field effect transistor and the second voltage dividing device are directly connected to two input nodes of the differential amplifier.

In one embodiment, the design structure comprises a netlist.

In another embodiment, the design structure resides on storage medium as a data format used for exchange of layout data of integrated circuits.

In even another embodiment, the first field effect transistor and the second field effect transistor are p-type field effect transistors, and a first source of the first field effect transistor and a second source of the second field effect transistor are directly connected to each other.

In yet another embodiment, the first voltage dividing device is a first n-type field effect transistor and the second voltage dividing device is a second n-type field effect transistor, and a third source of the first n-type field effect transistor and a fourth source of the second n-type field effect transistor are directly connected to each other.

In still another embodiment, the first n-type field effect transistor has a third threshold voltage and the second n-type field effect transistor has a fourth threshold voltage, and the first threshold voltage is greater than the second threshold voltage and the fourth threshold voltage is greater than the third threshold voltage.

In still yet another embodiment, the first voltage dividing device is a first resistor and the second voltage dividing device is a resistor, and an end terminal of the first resistor is directly connected to an end terminal of the second resistor.

In a further embodiment, the first field effect transistor and the second field effect transistor are n-type field effect transistors, and a first source of the first field effect transistor and a second source of the second field effect transistor are directly connected to each other.

In an even further embodiment, the first voltage dividing device is a first resistor and the second voltage dividing device is a resistor, and wherein an end terminal of the first resistor is directly connected to an end terminal of the second resistor.

In a yet further embodiment, the design structure further comprises a fourth data representing a circuit enable transistor that is serially connected to the parallel connection and configured to function as a switch between the parallel connection and one of ground and a positive power supply.

### BRIEF DESCRIPTION OF THE DRAWINGS

FIGS. 1-3 are first through third exemplary semiconductor circuits according to a first, a second, and a third embodiment of the present invention, respectively.

FIG. 4 is an exemplary control method that may be employed to advantageously use the inventive semiconductor circuits of the present invention.

FIG. 5 is a flow diagram of a design process used in semiconductor design and manufacture of the inventive semiconductor circuits according to the present invention.

### DETAILED DESCRIPTION OF THE INVENTION

As stated above, the present invention relates to a semiconductor circuit for detecting performance inversion of a set of semiconductor transistors, and a design structure for the same, which are now described in detail with accompanying figures. It is noted that like and corresponding elements are referred to by like names or reference numerals in the figures.

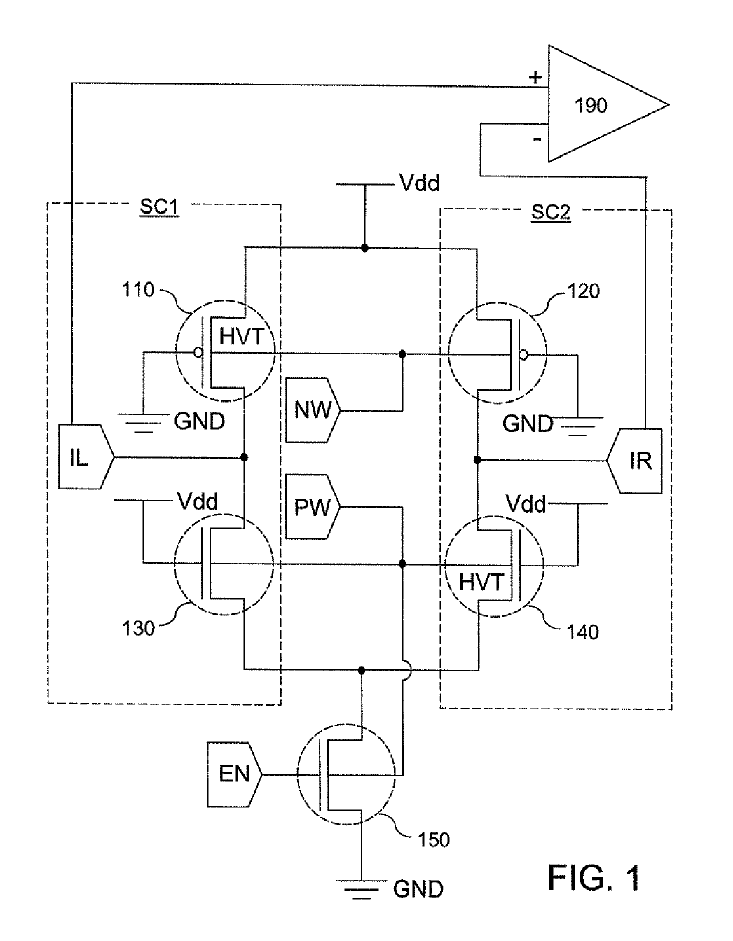

Referring to FIG. 1, a first exemplary semiconductor circuit according to a first embodiment of the present invention comprises a parallel connection of a first sub-circuit SC1 and a second sub-circuit SC2. The first sub-circuit SC1 comprises a serial connection of a first p-type field effect transistor 110 and a first n-type field effect transistor 130. The second sub-circuit SC2 comprises a serial connection of a second p-type field effect transistor 120 and a second n-type field effect transistor 140.

Each of the first p-type field effect transistor 110 and the first n-type field effect transistor 130 are voltage dividing devices, which provides a first voltage to a left internal node IL at which the drain of the first p-type field effect transistor 110 and the drain of the first n-type field effect transistor 130 are directly connected to each other. The drain of the first p-type field effect transistor 110 is herein referred to as a first p-type field effect transistor drain, and the drain of the first n-type field effect transistor 130 is herein referred to as a first n-type field effect transistor drain. In other words, a non-zero voltage is present across each of the first p-type field effect transistor 110 and the first n-type field effect transistor 130 when current flows through the first sub-circuit SC1.

Similarly, each of the second p-type field effect transistor 120 and the second n-type field effect transistor 140 are also voltage dividing devices, which provides a second voltage to a right internal node IR at which the drain of the second p-type field effect transistor 120, which is herein referred to as a second p-type field effect transistor drain, and the drain of the second n-type field effect transistor 140, which is herein referred to as a second n-type field effect transistor drain are directly connected to each other. A non-zero voltage is present across each of the second p-type field effect transistor 120 and the second n-type field effect transistor 140 when current flows through the second sub-circuit SC2.

The gates of the first and second p-type field effect transistors (110, 120) are grounded so that the first and second p-type field effect transistors (110, 120) are always turned on, and operates as voltage dividing devices when any current flows through the first sub-circuit SC1 or the second sub-circuit SC2, respectively. Likewise, the gates of the first and second n-type field effect transistors (130, 140) are connected to a positive power supply Vdd so that the first and second n-type field effect transistors (130, 140) are always turned on, and operates as voltage dividing devices when any current flows through the first sub-circuit SC1 or the second sub-circuit SC2, respectively. The positive power supply may provide a constant voltage to circuit components including the first exemplary semiconductor circuit, and the voltage that the positive power supply provides may be from about 0.4 V to about 3.0 V, and preferably from about 0.7 V to about 1.2V, although higher and lower voltages are also contemplated herein. Embodiments in which the gates of the first and second p-type field effect transistors (110, 120) and/or the gates of the first and second n-type field effect transistors (130, 140) are connected to electronic switches, which may comprise at least one transistor, are explicitly contemplated herein also.

The first and second p-type field effect transistors (110, 120) and the first and second n-type field effect transistors (130, 140) are preferably bulk devices, i.e., devices formed on a bulk semiconductor substrate that does not include a buried insulator layer or on a bulk portion of a hybrid substrate, although implementation of the present invention on semiconductor-on-insulator devices is also explicitly contemplated herein. In case the first and second p-type field effect transistors (110, 120) are bulk devices, the first and second p-type field effect transistors (110, 120) are formed in n-type wells or n-doped portions of a semiconductor substrate, which are electrically connected to, and biased at, an n-well bias node NW. Typically, the n-well bias node NW is connected to electrical ground, although biasing of the n-well bias node NW at a non-zero voltage is explicitly contemplated herein also. In case the first and second n-type field effect transistors (130, 140) are bulk devices, the first and second n-type field effect transistors (130, 140) are formed in p-type wells or p-doped portions of a semiconductor substrate, which are electrically connected to, and biased at, a p-well bias node PW. Typically, the p-well bias node PW is connected to the positive power supply Vdd, although biasing of the p-well bias node PW at a voltage other than the power supply voltage Vdd is explicitly contemplated herein also.

The source of the first p-type field effect transistor 110, which is herein referred to as a first p-type field effect transistor source, and the source of the second p-type field effect transistor 120, which is herein referred to as a second p-type field effect transistor source, are directly connected to each other. The sources of the first and second p-type field effect transistors (110, 120) may be directly connected to the positive power supply Vdd. Alternately, the sources of the first and second p-type field effect transistors (110, 120) may be indirectly connected to the positive power supply Vdd through at least one switch (not shown), which may comprise a power supply side circuit enable transistor (not shown).

The source of the first n-type field effect transistor 130, which is herein referred to as a first n-type field effect transistor source, and the source of the second n-type field effect transistor 140, which is herein referred to as a second n-type field effect transistor source, are directly connected to each other. The sources of the first and second n-type field effect transistors (130, 140) may be indirectly connected to ground through a circuit enable transistor 150. The circuit enable transistor 150 is serially connected to the parallel connection of the first sub-circuit SC1 and the second sub-circuit SC2 at the node at which the sources of the first and second n-type field effect transistors (130, 140) are connected to each other. The gate of the circuit enable transistor 150 is connected to a circuit enable signal node EN to function as a switch between the parallel connection and ground. Alternately, the sources of the first and second n-type field effect transistors (110, 120) may be directly connected to ground. The body of the circuit enable transistor 150 may be connected to the p-well bias node PW.

The first exemplary semiconductor circuit further comprises a differential amplifier 190 that compares voltages at two input nodes, labeled “+” and “−” respectively, and provides an output that depends on the sign of the voltage difference across the two input nodes. For example, the differential amplifier 190 may be an OP amplifier (OP amp). Specifically, the first voltage from the left internal node IL is provided to one of the two input nodes of the differential amplifier 190, and the second voltage from the right internal node IR is provided to the other of the two input nodes of the differential amplifier 190. Depending on whether the first voltage is greater than or less than the second voltage, the output of the differential amplifier 190 changes.

The first p-type field effect transistor has a first threshold voltage, the second p-type field effect transistor has a second threshold voltage, the first n-type field effect transistor has a third threshold voltage, and the second n-type field effect transistor has a fourth threshold voltage. At least one of the pair of the first threshold voltage and the second threshold voltage and the pair of the third threshold voltage and the fourth threshold voltage is not matched. In other words, the first threshold voltage is not the same as the second threshold voltage or the third threshold voltage is not the same as the fourth threshold voltage. Both pairs may be unmatched.

While any combination of relative differences in threshold voltages across the first and second p-type field effect transistors (110, 120) and the across the first and second n-type field effect transistors (130, 140) are possible, it is assumed herein, for the purposes of description of the present invention, that the first threshold voltage is greater than the second threshold voltage and that the fourth threshold voltage is greater than the third threshold voltage for the purposes of description of the present invention. For example, the first p-type field effect transistor and the second n-type field effect transistor may belong to a class of devices that are conventionally called high threshold voltage (high-Vt) devices, while the second p-type field effect transistor and the first n-type field effect transistor may belong to a class of devices that are conventionally called regular threshold voltage (regular-Vt) devices. In general, the first and second p-type field effect transistors (110, 120) may be selected from different classes of p-type field effect transistor devices available in a technology offering, which are characterized by the level of leakage current per unit width and/or the level of on-current per unit width. Likewise, the first and second n-type field effect transistors (130, 140) may be selected from different classes of n-type field effect transistor devices available in a technology offering, which are characterized by the level of leakage current per unit width and/or the level of on-current per unit width.

As discussed above, the differences in the threshold voltages across a pair of transistors of the same type induces different fractional change in the on-current as a function of operating temperature so that the voltage change across each transistor has a different temperature response depending on the threshold voltages. The first exemplary semiconductor circuit is designed so that the first voltage at the left internal node IL and the second voltage at the right internal node IR are matched at a temperature, which is herein referred to a “reference temperature,” which is selected to be between a lowest operating temperature, which is typically −40° C., and a highest operating temperature, which is typically 125° C. The current through the first sub-circuit SC1 may, or may not, be the same as the current through the second sub-circuit SC2 at the reference temperature.

At a temperature higher than the reference temperature, the high threshold voltage devices, i.e., the first p-type field effect transistor 110 and the second n-type field effect transistor 140, have a greater fractional increase within increasing temperature in on-current per unit temperature change than low threshold voltage devices, i.e., the second p-type field effect transistor 120 and the first n-type field effect transistor 130. Thus, when the circuit enable transistor 150 is turned on and the ambient temperature of the devices that the first exemplary semiconductor circuit is implemented in is higher than the reference temperature, the first voltage at the left internal node IL is higher than the second voltage at the right internal node IR.

Further, at a temperature lower than the reference temperature, the high threshold voltage devices, i.e., the first p-type field effect transistor 110 and the second n-type field effect transistor 140, have a greater fractional decrease with decreasing temperature in on-current per unit temperature change than low threshold voltage devices, i.e., the second p-type field effect transistor 120 and the first n-type field effect transistor 130. Thus, when the circuit enable transistor 150 is turned on and the ambient temperature of the devices that the first exemplary semiconductor circuit is implemented in is lower than the reference temperature, the first voltage at the left internal node IL is lower than the second voltage at the right internal node IR.

As the difference between the first voltage and the second voltage changes signs, the output of the differential amplifier 190 changes. The output, as an indicator of the ambient temperature of the region of a semiconductor chip in which an implementation of the first exemplary semiconductor circuit is located, may then be employed as a control signal for changing behavior of other circuits for optimized performance.

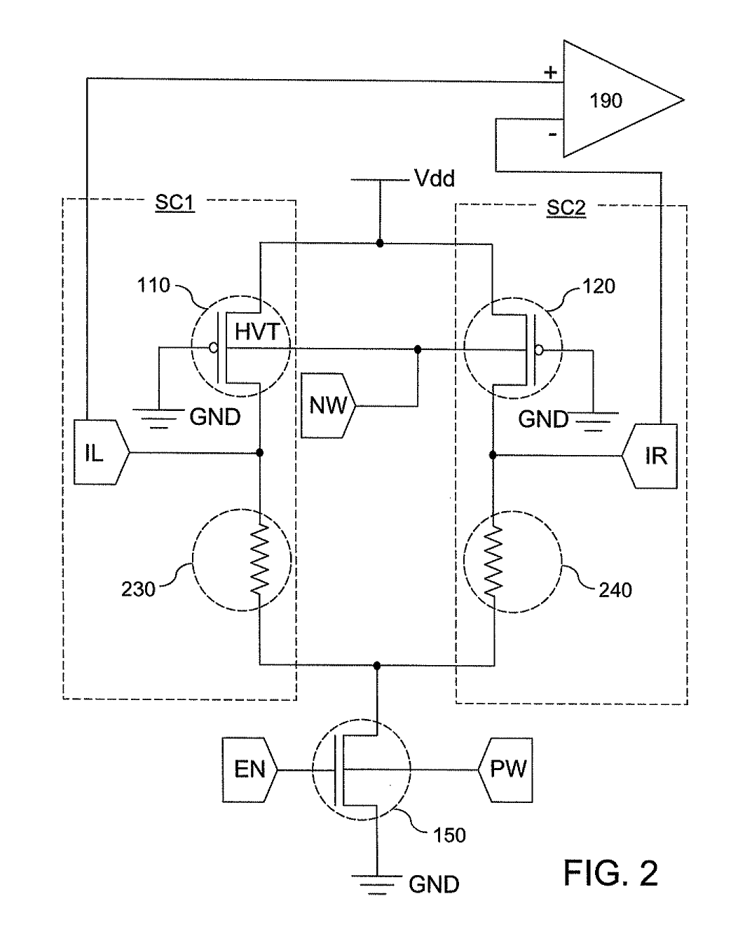

Referring to FIG. 2, a second exemplary semiconductor circuit according to a second embodiment of the present invention comprises a parallel connection of a first sub-circuit SC1 and a second sub-circuit SC2 as in the first embodiment. The first sub-circuit SC1 comprises a serial connection of a first p-type field effect transistor 110 and a first resistor 230, which may be, for example, a polysilicon resistor or a metal resistor. The second sub-circuit SC2 comprises a serial connection of a second p-type field effect transistor 120 and a second resistor 240, which may be, for example, a polysilicon resistor or a metal resistor.

Each of the first p-type field effect transistor 110 and the first resistor 230 are voltage dividing devices, which provides a first voltage to a left internal node IL, at which the drain of the first p-type field effect transistor 110, which is herein referred to as a first p-type field effect transistor drain, and a first terminal of the first resistor 230 are directly connected to each other. In other words, a non-zero voltage is present across each of the first p-type field effect transistor 110 and the first resistor 230 when current flows through the first sub-circuit SC1.

Similarly, each of the second p-type field effect transistor 120 and the second resistor 240 are also voltage dividing devices, which provides a second voltage to a right internal node IR at which the drain of the second p-type field effect transistor 120, which is herein referred to as a second p-type field effect transistor drain, and a first terminal of the second resistor 240 are directly connected to each other. A non-zero voltage is present across each of the second p-type field effect transistor 120 and the second resistor 240 when current flows through the second sub-circuit SC2.

The gates of the first and second p-type field effect transistors (110, 120) are grounded so that the first and second p-type field effect transistors (110, 120) are always turned on, and operates as voltage dividing devices when any current flows through the first sub-circuit SC1 or the second sub-circuit SC2, respectively. Embodiments in which the gates of the first and second p-type field effect transistors (110, 120) are connected to electronic switches, which may comprise at least one transistor, are explicitly contemplated herein also.

The first and second p-type field effect transistors (110, 120) are preferably bulk devices, although implementation of the present invention on semiconductor-on-insulator devices is also explicitly contemplated herein. In case the first and second p-type field effect transistors (110, 120) are bulk devices, the first and second p-type field effect transistors (110, 120) are formed in n-type wells or n-doped portions of a semiconductor substrate, which are electrically connected to, and biased at, an n-well bias node NW. Typically, the n-well bias node NW is connected to electrical ground, although biasing of the n-well bias node NW at a non-zero voltage is explicitly contemplated herein also.

The source of the first p-type field effect transistor 110, which is herein referred to as a first p-type field effect transistor source, and the source of the second p-type field effect transistor 120, which is herein referred to as a second p-type field effect transistor source, are directly connected to each other. The sources of the first and second p-type field effect transistors (110, 120) may be directly connected to the positive power supply Vdd. Alternately, the sources of the first and second p-type field effect transistors (110, 120) may be indirectly connected to the positive power supply Vdd through at least one switch (not shown), which may comprise a power supply side circuit enable transistor (not shown).

A second terminal of the first resistor 230 and a second terminal of the second resistor 240 are directly connected to each other. The second terminals of the first and second resistors (230, 240) may be indirectly connected to ground through a circuit enable transistor 150. The circuit enable transistor 150 is serially connected to the parallel connection of the first sub-circuit SC1 and the second sub-circuit SC2. The gate of the circuit enable transistor 150 is connected to a circuit enable signal node EN to function as a switch between the parallel connection and ground. Alternately, the second terminals of the first and second resistors (230, 240) may be directly connected to ground. The body of the circuit enable transistor 150 may be connected to a p-well bias node PW.

The second exemplary semiconductor circuit further comprises a differential amplifier 190 that compares voltages at two input nodes, labeled “+” and “−” respectively, as in the first embodiment. The first p-type field effect transistor 110 has a first threshold voltage and the second p-type field effect transistor 120 has a second threshold voltage. The first threshold voltage and the second threshold voltage are not matched.

While either of the first and second p-type field effect transistors (110, 120) may have a higher threshold voltage relative to the other, it is assumed herein, for the purposes of description of the present invention, that the first threshold voltage is greater than the second threshold voltage. For example, the first p-type field effect transistor 110 may belong to a class of devices that are conventionally called high threshold voltage (high-Vt) devices, while the second p-type field effect transistor 120 may belong to a class of devices that are conventionally called regular threshold voltage (regular-Vt) devices. In general, the first and second p-type field effect transistors (110, 120) may be selected from different classes of p-type field effect transistor devices available in a technology offering, which are characterized by the level of leakage current per unit width and/or the level of on-current per unit width.

As discussed above, the differences in the threshold voltages across a pair of transistors of the same type induces different fractional change in the on-current as a function of operating temperature so that the voltage change across each transistor has a different temperature response depending on the threshold voltages. The second exemplary semiconductor circuit is designed so that the first voltage at the left internal node IL and the second voltage at the right internal node IR are matched at a temperature, which is herein referred to a “reference temperature,” which is selected to be between a lowest operating temperature, which is typically −40° C., and a highest operating temperature, which is typically 125° C. For this purpose, the resistance of the first resistor 230 may, or may not, match the resistance of the second resistor 240. Therefore, the current through the first sub-circuit SC1 may, or may not, be the same as the current through the second sub-circuit SC2 at the reference temperature.

At a temperature higher than the reference temperature, the first p-type field effect transistor 110 has a greater fractional increase within increasing temperature in on-current per unit temperature change than the second p-type field effect transistor 120. Thus, when the circuit enable transistor 150 is turned on and the ambient temperature of the devices that the second exemplary semiconductor circuit is implemented in is higher than the reference temperature, the first voltage at the left internal node IL is higher than the second voltage at the right internal node IR.

Further, at a temperature lower than the reference temperature, the first p-type field effect transistor 110 has a greater fractional decrease with decreasing temperature in on-current per unit temperature change than the second p-type field effect transistor 120. Thus, when the circuit enable transistor 150 is turned on and the ambient temperature of the devices that the second exemplary semiconductor circuit is implemented in is lower than the reference temperature, the first voltage at the left internal node IL is lower than the second voltage at the right internal node IR.

As in the first embodiment, a change of sign in the difference between the first voltage and the second voltage at the input nodes of the differential amplifier 190 induces a change in the output of the differential amplifier 190. The output, as an indicator of the ambient temperature of the region of a semiconductor chip in which an implementation of the first exemplary semiconductor circuit is located, may then be employed as a control signal for changing behavior of other circuits for optimized performance.

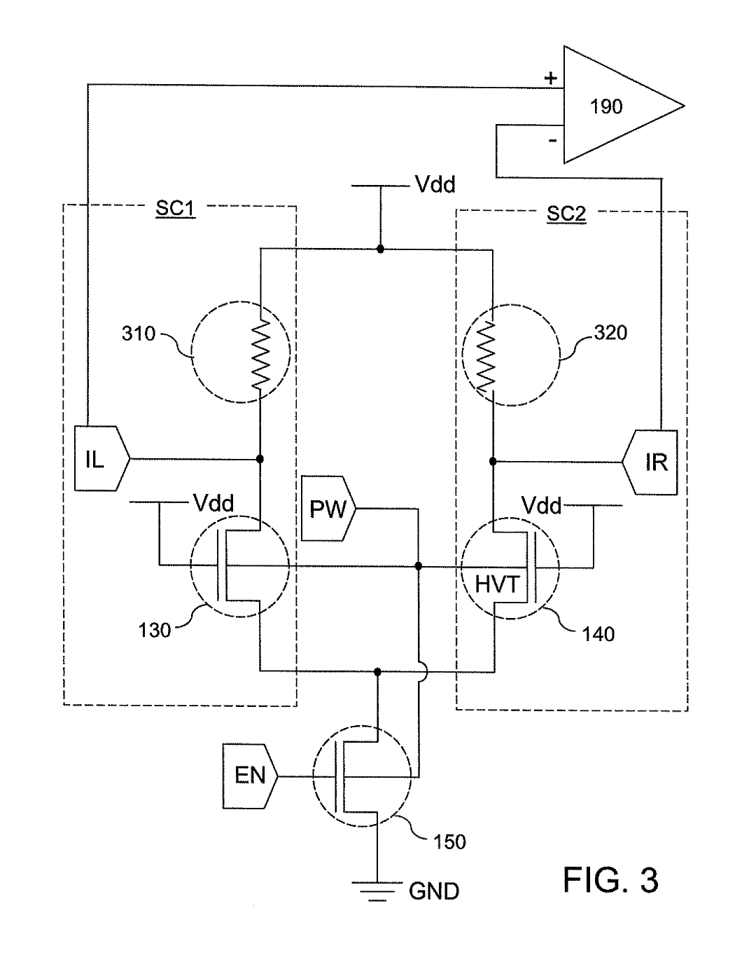

Referring to FIG. 3, a third exemplary semiconductor circuit according to a third embodiment of the present invention comprises a parallel connection of a first sub-circuit SC1 and a second sub-circuit SC2 as in the first embodiment. The first sub-circuit SC1 comprises a serial connection of a first n-type field effect transistor 130 and a first resistor 310, which may be, for example, a polysilicon resistor or a metal resistor. The second sub-circuit SC2 comprises a serial connection of a second n-type field effect transistor 140 and a second resistor 320, which may be, for example, a polysilicon resistor or a metal resistor.

Each of the first n-type field effect transistor 130 and the first resistor 310 are voltage dividing devices, which provides a first voltage to a left internal node IL, at which the drain of the first n-type field effect transistor 130, which is herein referred to as a first p-type field effect transistor drain, and a first terminal of the first resistor 310 are directly connected to each other. In other words, a non-zero voltage is present across each of the first n-type field effect transistor 130 and the first resistor 310 when current flows through the first sub-circuit SC1.

Similarly, each of the second n-type field effect transistor 140 and the second resistor 320 are also voltage dividing devices, which provides a second voltage to a right internal node IR at which the drain of the second n-type field effect transistor 140, which is herein referred to as a second p-type field effect transistor drain, and a first terminal of the second resistor 320 are directly connected to each other. A non-zero voltage is present across each of the second n-type field effect transistor 140 and the second resistor 320 when current flows through the second sub-circuit SC2.

The gates of the first and second n-type field effect transistors (130, 140) are connected to a positive power supply Vdd so that the first and second n-type field effect transistors (130, 140) are always turned on, and operates as voltage dividing devices when any current flows through the first sub-circuit SC1 or the second sub-circuit SC2, respectively. Embodiments in which the gates of the first and second n-type field effect transistors (130, 140) are connected to electronic switches, which may comprise at least one transistor and may be connected or disconnected from the positive power supply, are explicitly contemplated herein also.

The first and second n-type field effect transistors (130, 140) are preferably bulk devices, although implementation of the present invention on semiconductor-on-insulator devices is also explicitly contemplated herein. In case the first and second n-type field effect transistors (130, 140) are bulk devices, the first and second n-type field effect transistors (130, 140) are formed in p-type wells or p-doped portions of a semiconductor substrate, which are electrically connected to, and biased at, a p-well bias node PW. Typically, the p-well bias node PW is connected to the positive power supply, although biasing of the p-well bias node PW at a voltage different from the voltage of the positive power supply is explicitly contemplated herein also.

The source of the first n-type field effect transistor 130, which is herein referred to as a first n-type field effect transistor source, and the source of the second n-type field effect transistor 140, which is herein referred to as a second n-type field effect transistor source, are directly connected to each other. The sources of the first and second n-type field effect transistors (130, 140) may be indirectly connected to electrical ground through a circuit enable transistor 150 as in the first embodiment. Alternately, the sources of the first and second n-type field effect transistors (130, 140) may be directly connected to electrical ground. A second terminal of the first resistor 310 and a second terminal of the second resistor 320 are directly connected to each other. The second terminals of the first and second resistors (310, 320) may be directly connected to the positive power supply Vdd.

The third exemplary semiconductor circuit further comprises a differential amplifier 190 that compares voltages at two input nodes, labeled “+” and “−” respectively, as in the first embodiment. The first n-type field effect transistor 130 has a first threshold voltage and the second n-type field effect transistor 140 has a second threshold voltage. The first threshold voltage and the second threshold voltage are not matched.

While either of the first and second n-type field effect transistors (130, 140) may have a higher threshold voltage relative to the other, it is assumed herein, for the purposes of description of the present invention, that the second threshold voltage is greater than the first threshold voltage. For example, the second n-type field effect transistor 140 may belong to a class of devices that are conventionally called high threshold voltage (high-Vt) devices, while the first n-type field effect transistor 130 may belong to a class of devices that are conventionally called regular threshold voltage (regular-Vt) devices. In general, the first and second n-type field effect transistors (130, 140) may be selected from different classes of p-type field effect transistor devices available in a technology offering, which are characterized by the level of leakage current per unit width and/or the level of on-current per unit width.

As discussed above, the differences in the threshold voltages across a pair of transistors of the same type induces different fractional change in the on-current as a function of operating temperature so that the voltage change across each transistor has a different temperature response depending on the threshold voltages. The third exemplary semiconductor circuit is designed so that the first voltage at the left internal node IL and the second voltage at the right internal node IR are matched at a temperature, which is herein referred to a “reference temperature,” which is selected to be between a lowest operating temperature, which is typically −40° C., and a highest operating temperature, which is typically 125° C. For this purpose, the resistance of the first resistor 310 may, or may not, match the resistance of the second resistor 320. Therefore, the current through the first sub-circuit SC1 may, or may not, be the same as the current through the second sub-circuit SC2 at the reference temperature.

At a temperature higher than the reference temperature, the second n-type field effect transistor 140 has a greater fractional increase within increasing temperature in on-current per unit temperature change than the first n-type field effect transistor 130. Thus, when the circuit enable transistor 150 is turned on and the ambient temperature of the devices that the third exemplary semiconductor circuit is implemented in is higher than the reference temperature, the first voltage at the left internal node IL is higher than the second voltage at the right internal node IR.

Further, at a temperature lower than the reference temperature, the second n-type field effect transistor 140 has a greater fractional decrease with decreasing temperature in on-current per unit temperature change than the first n-type field effect transistor 130. Thus, when the circuit enable transistor 150 is turned on and the ambient temperature of the devices that the third exemplary semiconductor circuit is implemented in is lower than the reference temperature, the first voltage at the left internal node IL is lower than the second voltage at the right internal node IR.

As in the first embodiment, a change of sign in the difference between the first voltage and the second voltage at the input nodes of the differential amplifier 190 induces a change in the output of the differential amplifier 190. The output, as an indicator of the ambient temperature of the region of a semiconductor chip in which an implementation of the first exemplary semiconductor circuit is located, may then be employed as a control signal for changing behavior of other circuits for optimized performance.

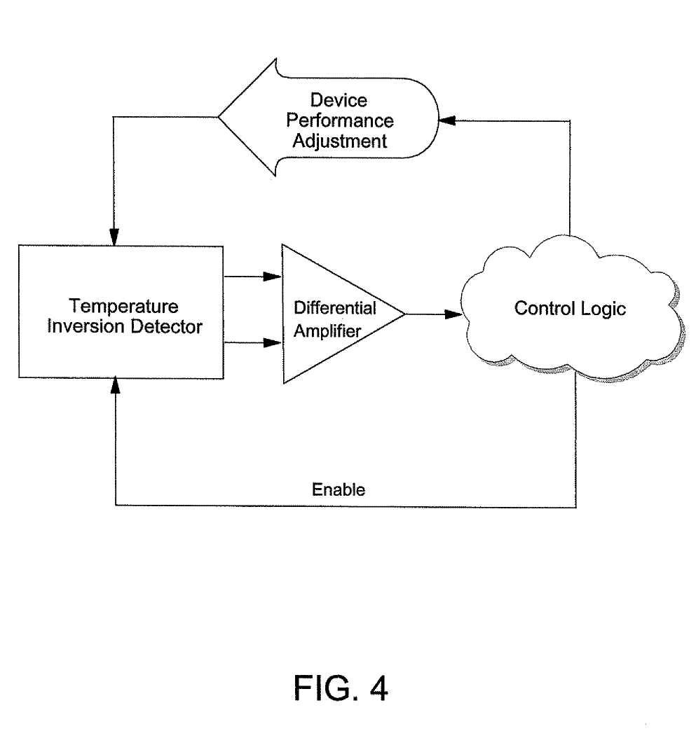

FIG. 4 shows an exemplary method of employing the output of the first through third exemplary semiconductor circuits for adjusting operation of devices in a semiconductor chip. The combination of the first and second sub-circuits (SC1 and SC2) and the optional circuit enable transistor 150 or its equivalent constitutes a temperature inversion detector. The differential amplifier of FIG. 4 is the same as the differential amplifier 190 of the first through third exemplary semiconductor circuits. The control logic may be provided by another circuit in the semiconductor chip configured to adjust device performance parameters such as well bias, power supply voltage, and/or back bias voltage on devices having a back side gate or an equivalent structure. The adjustment in device performance may induce changes in the temperature of the semiconductor chip, which is then detected by the temperature inversion sensor of the present invention, and if the temperature crosses over the reference temperature of the temperature inversion sensor, a change in the output of the differential amplifier may trigger additional changes in the control logic. More than one temperature inversion detector may be employed to monitor performance of many classes of semiconductor devices having different levels of leakage current, and/or to provide multiple reference temperatures with which to generate sophisticated instructions from the control logic.

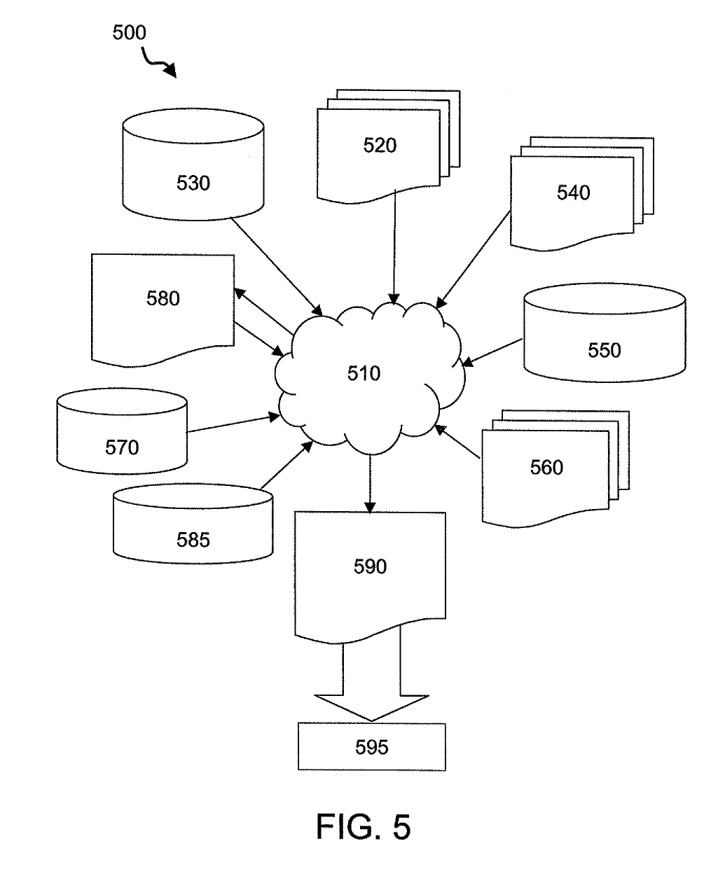

FIG. 5 shows a block diagram of an exemplary design flow 500 used for example, in semiconductor design and manufacturing. Design flow 500 may vary depending on the type of IC being designed. For example, a design flow for building an application specific integrated circuit (ASIC) may differ from a design flow for designing a standard integrated circuit component. Design structure 520 is preferably an input to a design process 510 and may come from an intellectual property (IP) provider, a core developer, or a design company, or may be generated by the operator of a design flow, or may come from other sources.

Design structure 520 comprises an embodiment of present invention as shown in FIGS. 1-3 in the form of schematics or HDL, hardware description language (e.g. Verilog, VHDL, C, etc.) The design structure 520 may be contained on one or more machine readable medium. For example, design structure 520 may be a text file or a graphical representation of an embodiment of the invention as shown in FIGS. 1-3.

Design process 510 preferably synthesizes (or translates) an embodiment of the invention as show in FIGS. 1-3 into a netlist 580, where the netlist 580 is, for example, a list of wires, transistors, logic gates, control circuits, I/O, models, etc. that describes the connections to other elements and circuits in an integrated circuit design and recorded on at least one of machine readable medium. For example, the medium may be a CD, a compact flash, other flash memory, a packet of data to be sent via the Internet, or other networking suitable means. The synthesis may be an iterative process in which the netlist 580 is resynthesized one or more times depending on design specifications and parameters for the circuit.

The design process 510 may include using a variety of inputs; for example, inputs from library elements 530 which may house a set of commonly used elements, circuits, and devices, including models, layouts, and symbolic representations, for a given manufacturing technology (e.g., different technology nodes such as 32 nm, 45 nm, and 50 nm, etc.), design specifications 540, characterization data 550, verification data 560, design rules 570, and test data files 585 (which may include, for example, standard circuit design processes such as timing analysis, verification, design rule checking, place and route operations, etc. One of ordinary skill in the art of integrated circuit design can appreciate the extent of possible electronic design automation tools and applications used in the design process 510 without deviating from the scope and spirit of the present invention. The design structure of the present invention is not limited to any specific design flow.

Design process 510 preferably translates an embodiment of the invention as shown in FIG. 2, along with any additional integrated circuit deign or data (if applicable), into a second design structure 590. Design structure 590 resides on a storage medium in a data format used for the exchange of layout data of integrated circuits and/or symbolic data format (e.g., information stored in GDSII (GDS2), GL1, OASIS, map files, or any other suitable format for storing such design structures). Design structure 590 may comprise information such as, for example, symbolic data, map files, test data files, design content files, manufacturing data, layout parameters, wires, levels of metal, vias, shapes, data for routing though the manufacturing line, and any other data required by a semiconductor manufacturer to produce an embodiment of the invention as shown in FIGS. 1-3. Design structure 590 may then proceed to a stage 595 where, for example, design structure 590 proceeds to tape-out, is released to manufacturing, is released to a mask house, is sent to another design house, is sent back to a customer, etc.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A semiconductor circuit comprising a parallel connection of a first sub-circuit and a second sub-circuit and a differential amplifier, wherein said first sub-circuit comprises a serial connection of a first field effect transistor having a first threshold voltage and a first voltage dividing device, wherein said second sub-circuit comprises a serial connection of a second field effect transistor having a second threshold voltage and a second voltage dividing device, wherein said first threshold voltage is different from said second threshold voltage, and wherein a first voltage from a first internal node between said first field effect transistor and said first voltage dividing device and a second voltage from a second internal node between said second field effect transistor and said second voltage dividing device are compared by said differential amplifier.

2. The semiconductor circuit of claim 1, wherein said first field effect transistor and said second field effect transistor are p-type field effect transistors, and wherein a first source of said first field effect transistor and a second source of said second field effect transistor are directly connected to each other.

3. The semiconductor circuit of claim 2, wherein said first voltage dividing device is a first n-type field effect transistor and said second voltage dividing device is a second n-type field effect transistor, and wherein a third source of said first n-type field effect transistor and a fourth source of said second n-type field effect transistor are directly connected to each other.

4. The semiconductor circuit of claim 3, wherein said first n-type field effect transistor has a third threshold voltage and said second n-type field effect transistor has a fourth threshold voltage, wherein said first threshold voltage is greater than said second threshold voltage and said fourth threshold voltage is greater than said third threshold voltage.

5. The semiconductor circuit of claim 2, wherein said first voltage dividing device is a first resistor and said second voltage dividing device is a resistor, and wherein an end terminal of said first resistor is directly connected to an end terminal of said second resistor.

6. The semiconductor circuit of claim 2, wherein said first source and said second source are connected to a positive power supply.

7. The semiconductor circuit of claim 1, wherein said first field effect transistor and said second field effect transistor are n-type field effect transistors, and wherein a first source of said first field effect transistor and a second source of said second field effect transistor are directly connected to each other.

8. The semiconductor circuit of claim 7, wherein said first voltage dividing device is a first resistor and said second voltage dividing device is a resistor, and wherein an end terminal of said first resistor is directly connected to an end terminal of said second resistor.

9. The semiconductor circuit of claim 1, further comprising a circuit enable transistor that is serially connected to said parallel connection and configured to function as a switch between said parallel connection and one of ground and a positive power supply.

10. The semiconductor circuit of claim 1, wherein said first field effect transistor and said second field effect transistor are constantly turned on and said first voltage dividing device and said second voltage dividing device are configured to pass current upon application of a voltage differential thereacross.

11. A design structure embodied in a machine readable medium for designing, manufacturing, or testing a design, said design structure representing a semiconductor circuit and comprising:
a first data representing a serial connection of a first field effect transistor having a first threshold voltage and a first voltage dividing device;
a second data representing a serial connection of a second field effect transistor having a second threshold voltage and a second voltage dividing device; and
a third data representing a differential amplifier, wherein said first serial connection and said second serial connection are configured in a parallel connection in said semiconductor circuit, and wherein a first internal node between said first field effect transistor and said first voltage dividing device and a second internal node between said second field effect transistor and said second voltage dividing device are directly connected to two input nodes of said differential amplifier.

12. The design suture of claim 11, wherein said design structure comprises a netlist.

13. The design structure of claim 11, wherein said design structure resides on storage medium as a data format used for exchange of layout data of integrated circuits.

14. The design structure of claim 11, wherein said first field effect transistor and said second field effect transistor are p-type field effect transistors, and wherein a first source of said first field effect transistor and a second source of said second field effect transistor are directly connected to each other.

15. The design structure of claim 12, wherein said first voltage dividing device is a first n-type field effect transistor and said second voltage dividing device is a second n-type field effect transistor, and wherein a third source of said first n-type field effect transistor and a fourth source of said second n-type field effect transistor are directly connected to each other.

16. The design structure of claim 13, wherein said first n-type field effect transistor has a third threshold voltage and said second n-type field effect transistor has a fourth threshold voltage, wherein said first threshold voltage is greater than said second threshold voltage and said fourth threshold voltage is greater than said third threshold voltage.

17. The design structure of claim 14, wherein said first voltage dividing device is a first resistor and said second voltage dividing device is a resistor, and wherein an end terminal of said first resistor is directly connected to an end terminal of said second resistor.

18. The design structure of claim 11, wherein said first field effect transistor and said second field effect transistor are n-type field effect transistors, and wherein a first source of said first field effect transistor and a second source of said second field effect transistor are directly connected to each other.

19. The design structure of claim 18, wherein said first voltage dividing device is a first resistor and said second voltage dividing device is a resistor, and wherein an end terminal of said first resistor is directly connected to an end terminal of said second resistor.

20. The design structure of claim 11, further comprising a fourth data representing a circuit enable transistor that is serially connected to said parallel connection and configured to function as a switch between said parallel connection and one of ground and a positive power supply.
